(19) United States
(12) Patent Application Publication
(10) Pub. No.: US 2003/0087466 A1
(43) Pub. Date: May 8, 2003

(54) Phototransistor device

(76) Inventors: Yuqi Wang, Hong Kong (HK); Hailin Luo, Hong Kong (HK); Yuchhun Chang, Hong Kong (HK); Jiannong Wang, Hong Kong (HK); Weikun Ge, Hong Kong (HK)

Correspondence Address: James A. LaBarre, BURNS, DOANE, SWECKER & MATHIS, L.L.P., P.O. Box 1404, Alexandria, VA, 22313-1404, US

(21) Appl. No.: 09/985,877

(22) Filed: Nov. 6, 2001

(51) Int. Cl. H01L 21/00; H01L 33/00; H01L 21/66; G01R 31/26

(52) U.S. Cl. 438/45; 257/98; 438/17

(57) ABSTRACT

A phototransistor comprises a layer having two n-type semiconductor regions which constitute an emitter region and a collector region, and which sandwich a lightly doped p-type base region. In operating conditions the base region is completely depleted leading to punchthrough, and generation of high optical conversion gain when the phototransistor is illuminated. The base region and part of the emitter and collector regions are covered with an oxide layer. The phototransistor can be fabricated by CMOS processing technology, so very large scale integrated circuits can be fabricated comprising a large number of the phototransistors.

### FIELD OF THE INVENTION

The present invention relates to a heterojunction phototransistor device, and a method of operating the phototransistor device.

### BACKGROUND OF THE INVENTION

Photodetectors are essential components in various optoelectronic applications. Their function is to convert a received optical signal, such as an optical signal received along an optical fibre, into an electrical signal, which is then amplified before further processing. In order to achieve satisfactory overall system performance, several specific properties are required by the phototransistor. The most important of them are high sensitivity at the operating wavelength of the system, a speed of response compatible with the system data transmission rate and low noise generation. There are also some secondary considerations such as easy integration with preamplifiers and other functional circuits, power supply requirements and efficient coupling to the fibre. In some specific applications, these secondary considerations may be crucial. For example, easy integration with preamplifiers and other functional circuits is the top consideration for image pick-up sensors.

Presently, the most commonly used photodetectors are semiconductor p-i-n photodiodes and avalanche photodiodes (APD). These are modified p-n junction devices with additional layers at different doping levels to provide either more efficient quantum conversion or avalanche gain through impact ionization. Basically, in a reversed-biased photodiode, incident photons are absorbed in the depletion region and generate electron-hole pairs. Under the influence of the electric field in this region, the generated electrons and holes are swept rapidly to the n and p sides of the diode respectively, causing current to flow in the external circuit. In order to achieve high quantum efficiency, a relatively high resistivity intrinsic layer is inserted between the p-type and n-type materials resulting in a p-i-n photodiode. This intrinsic layer increases the depletion-region width, which increases absorption. Another approach for obtaining large detector current is to create an avalanche gain effect by operating the devices at a reverse bias voltage very near to the breakdown voltage, as in the APDs. In this case, an electron-hole pair can generate tens or hundreds more secondary electron-hole pairs. However, due to the random nature of the avalanche multiplication process, the excess noise generated in these devices, and this is a limiting factor on the detectivity and leads to a trade-off between the gain and noise for APDs.

Apart from p-i-n photodiodes and avalanche photodiodes, another kind of photodetector which satisfies many of the detector requirements of applications such as fibre communication systems, is termed a phototransistor. The phototransistor was first proposed by in 1951 soon after the establishment of the bipolar transistor in the late 1940s and first demonstrated in an n-p-n Ge structure in 1953. It is a bipolar junction transistor with a large base-collector junction acting as the light-collecting element. Such a phototransistor can provide large optical gain through the transistor action without excess noise. Hence, phototransistors may have better responsivity and detectivity than both p-i-n photodiodes and avalanche photodiodes. Most of the phototransistors studied today are two-terminal devices with a floating base, but such devices have drawbacks which limit their applications. At low incident optical power, the gain of the phototransistor is generally small due to recombination inside the base-emitter junction space charge region. The low incident optical power also leads to a longer charging time for the emitter junction capacitance. Consequently, the gain-bandwidth product f_{T} is small and the signal-to-noise ratio deteriorates at high-speed application, since the gain is close to unity when the operating frequency approaches f_{T}.

In order to improve the performance of the phototransistors, it is known to provide a base terminal. Enhanced performance was demonstrated for the first time by Fritzsche D., Kuphal. E. and Aulbach. R, Electron. Lett., 17, 178-180, 1981, who reported a 2 ns rise time in a three-terminal heterojunction phototransistor (HPT) by trading gain for bandwidth. Operation at 200 MHz was performed with an input optical power of 15 μW. It is now known that under an optimally chosen external base current, the optical gain of the device is enhanced more than 5 times compared to same transistor without bias, and the 3-dB bandwidth is 15 times higher than the two-terminal device over the same range of input optical power. Recently, Sridhara R., Frimel S. M., Poenker K. P., Pan N. and Elliot J., J. Lightwave Technol., 16, 1101-1106, 1998, illustrated the advantages of the three-terminal operation of HPT over the two-terminal configuration.

Although, there have been some successes in applying electrical bias to improve the gain and response speed of phototransistors, the amplified shot noise associated with the base bias current contributes a significant noise source to the total noise of the phototransistor. When the base bias current is much larger than the photogenerated current, the signal-to-noise ratio is seriously degraded due to the increased shot noise, which limits the detectivity of the device for weak light.

In order to improve the high-speed response and noise performance of the phototransistor, the emitter junction charging time has to be reduced by either increasing the collector bias current or lowering the emitter capacitance without introducing much noise associated with the base. Y. Wang, E. S. Yang and W. I. Wang (in J. Appl. Phys., 74, 6978-6981, 1993, the disclosure of which is incorporated herein by reference in its entirety) reported a novel structure punchthrough phototransistor which can simultaneously achieve high gain, high speed and low noise operation.

Punchthrough phototransistors (PTPT) have the merits of both the p-i-n photodiode (low noise) and the avalanche photodiode (high gain). Their noise performance is better than conventional phototransistors because there is no amplified shot noise associated with base bias current involved. Thus, they have advantages in detecting low optical power signal. Optical conversion gain as high as 1240 at an incident optical power as low as 0.5 pW with gain changes less than 15% over a 20 dB range of incident optical power was reported for an AlGaAs/GaAs/GaAs PTPT, shown in FIG. 6 of this application.

An N⁺ GaAs substrate 50, is covered by a GaAs buffer layer 52 in contact with a metal collector contact 54. The buffer layer 52 is covered by a N-type GaAs collector layer 56, which in turn is covered by a lightly-doped P-type GaAs base layer 58. The GaAs base layer 58 is covered by a N-type AlGaAs emitter layer 60, which in turn is covered by a GaAs cap layer 62. The cap layer 62 has two metal emitter contacts 64.

The signal-to-noise ratio at the output of a photodetector is defined by

$$\frac{S}{N} = \frac{signal power from photocurrent}{photo detector noise power plus circuit noise power}$$

The photodetector noise arises from the statistical nature of the photon-electron conversion processes and the circuit noise is associated with the thermal noise of load resistor. To achieve a high signal-to-noise ratio, the photodetector must have a high quantum efficiency of optical conversion gain to generate a large signal power. In addition, the photodetector and circuit noise should be kept as low as possible.

For the punchthrough phototransistor, the collector quiescent bias current is applied without the base bias current. If we neglect the correlation between the noise components associated with the collector quiescent bias current I_{cq} and the amplified photogenerated current, the output current noise can be written by equations given in the paper by Wang, Yang and Wang cited above.

To derive these equations two assumptions are made for simplicity. First, it is assumed that both the conventional and punch-through phototransistors have same current gain and current cut-off frequency f_{T}. Also neglected is the term related to the partition noise due to the random behaviour of electron-hole recombination in the neutral base region. In conventional phototransistors, this partition noise is a significant noise component when the transistors work at high frequencies. However, the punch-through phototransistors should not suffer from the partition noise as seriously as the conventional phototransistors, since there is no neutral base in the punchthrough phototransistors. If we further consider the facts of lower partition noise, higher current gain and higher current cutoff frequency of the PTPTs, the low noise performance of punchthrough phototransistors will be much better than that of the conventional phototransistors.

However, the known GaAs/AlGaAs phototransistor described above, in common other compound semiconductors devices, has two drawbacks. They are very hard to integrate cheaply with other functional circuits at low cost, and they have relatively high output noise due to base-collector junction leak current.

### SUMMARY OF THE INVENTION

The present invention aims to provide a new and useful phototransistor, as well as a method of operating the phototransistor.

In general terms, the present invention proposes that the emitter-base-collector structure is formed on a substrate as a single layer having regions appropriately doped to constitute the regions. As in the known phototransistor described above, the doping of the base region is low, so that in operation the base region is fully depleted.

This lateral structure is completely compatible with so-called CMOS technology, which makes the present invention attractive for many applications.

The structure of present structure may be realised in a structure in which the base, emitter and collector regions are doped regions of an element semiconductor (i.e. a semiconductor mainly composed of a single element such as Si, as opposed to a compound semiconductor such as GaAs). Generally, the substrate is formed of the same element semiconductor.

Generally, an oxide layer (e.g. SiO₂) is formed over at least some of the doped regions. In particular, it may substantially cover the base layer, and may cover at least part of the emitter and collector regions. Since the surface of the devices is well protected by the SiO₂, surface generations and recombinations may be reduced to a negligible level. This makes the gain higher and I_{CBO} smaller (The “O” subscript of I_{CBO} means in the condition in which the third terminal (here the emitter) is open circuit. In general, I_{CEO}=βI_{CBO} for some constant β).

These structures are completely compatible with CMOS processing technology. Therefore, very large scale integrated circuits can be fabricated incorporating multiple phototransistors according to the invention, to form structures such as camera sensors and OEICs (optoelectronic integrated circuits) for short wavelength optical fibre system receivers.

Furthermore, embodiments of the invention may have a faster response time than known compound based heterojunction devices because there is no extra barrier to block the photo generated carriers diffusing into the emitter side. By contrast the structure shown in FIG. 6 has a crystalline barrier between the GeAs base 58 and the AlGaAs emitter 60.

Optionally, an oxide (SiO₂) layer may be formed covering the substrate beneath the base, emitter and collector regions. In this case, the phototransistor may be even faster because all photo-generated carriers are confined to the strong-field region.

### BRIEF DESCRIPTION OF THE FIGURES

Embodiments of the invention will now be described in detail with reference to the following figures in which:

FIG. 1 shows in cross-section the structure of a first embodiment of the invention;

FIG. 2 shows in cross-section the structure of a second embodiment of the invention;

FIG. 3 shows experimental results indicating the gain and I-V characteristics of an embodiment of the invention;

FIG. 4 shows experimental results indicating the noise characteristics of an embodiment of the invention in dark conditions; and

FIG. 5 shows experimental results indicating the time response of an embodiment of the invention; and

FIG. 6 shows in cross-section the structure of a known phototransistor.

### DETAILED DESCRIPTION OF THE EMBODIMENTS

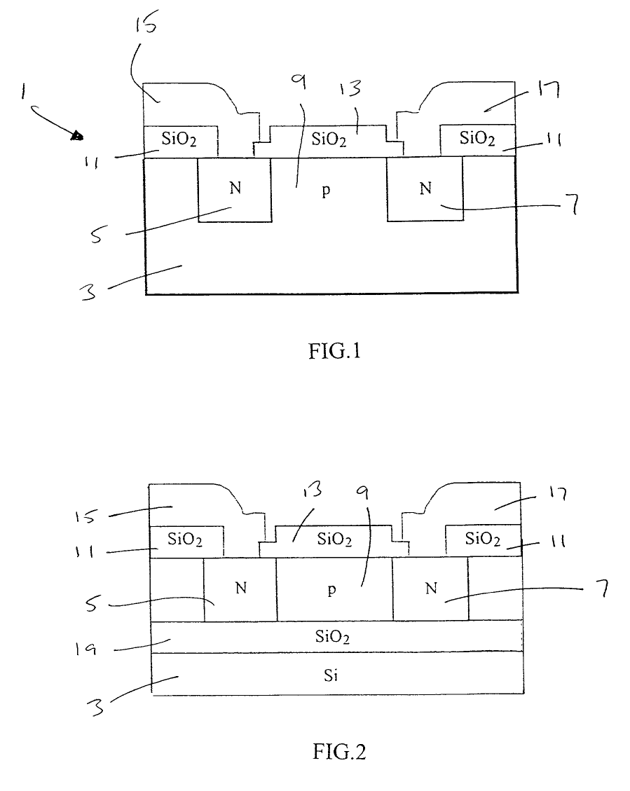

Referring firstly to FIG. 1, a phototransistor 1 which is a first embodiment of the invention is shown, formed on an Si substrate 3 containing, in a single top layer two N-doped Si regions 5,7 sandwiching a lightly-doped P⁻-type Si region 9. The region 5 constitutes the emitter region, and the region 7 constitutes the collector region, and the region 9 constitutes the base region.

Note that the layer including the regions 5, 7, 9 does not need to be of constant thickness. Rather each of the regions 5, 7, 9 may extend to a different distance towards (into) the substrate 3.

The semiconductor structure is covered by SiO₂ regions 11, 13. One of these SiO₂ regions 13 completely covers the base region 9, and part of the emitter and collector regions 5, 7. Ohmic contacts 15, 17 are provided respectively contacting the N-type regions 5, 7. The base region 9, however, does not have an Ohmic contact, and is floating.

Turning to FIG. 2, a second embodiment is shown. Regions corresponding to those of FIG. 1 are shown by the same reference numerals. The second embodiment differs from the embodiment of FIG. 2 by having an extra insulating SiO₂ layer 19 provided covering the Si substrate 3 below the doped regions 5, 7, 9.

The width of the layers in the devices (i.e. in the horizontal direction of the figure) is of the order of a few micrometers. The doping levels of the base region are preferably from 10¹⁵ cm⁻³ to 10¹⁶ cm⁻³. At the latter doping level the base width is preferably at most about 1 micrometer. At the former doping level, the base width can be higher, such as at most about 4 micrometers.

Under the normal operating conditions, such as with 2 to 6 volts emitter-collector bias, the base region 9 is completely depleted (punch-through).

In these conditions the barrier height of the base-emitter junction is lowered with increasing V_{CE} by the static induction effect, and the collector current increases exponentially with the increase in V_{CE}. The barrier height of the base-emitter junction can thus be adjusted by supplying bias voltage between the emitter and the collector. Thus, in dark conditions, the quiescent bias current is solely controlled by V_{CE}. When the device is illuminated however, electron-hole pairs are generated in the depleted base and the base-collector junction. The photo-generated electrons contribute a photo-current component to the collector current. In addition, the photo-generated holes are swept to the base-emitter junction. This increases the forward bias of the base-emitter junction, which causes a large electron injection from the emitter to the collector. The injected electrons are swept to the collector immediately after they pass through the barrier of the base-emitter junction since there is no neural base.

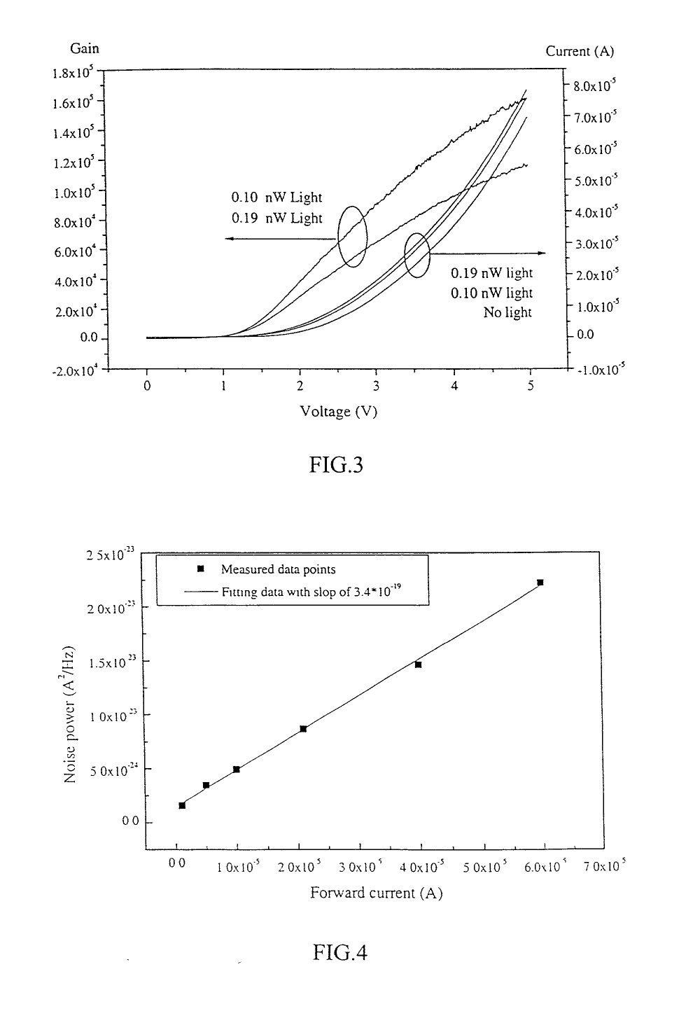

FIG. 3 shows the measured I-V curves for a device on a regular Si substrate with an area of 4×20 μm², a base doping level of about 10¹⁵ cm⁻³ and a base width of 4 micrometers, under different illumination conditions and optical conversion gains. Lines 101 and 102 show the gain at illumination powers of 0.1 nW and 0.19 nW respectively. Lines 103, 104, 105 show the current respectively without illumination and at illumination levels of 0.10 nW and 0.19 nW. Gains higher than 1.6×10⁵ were measured for an incident power of 0.1 nW, which roughly corresponds to the normal indoor illumination.

According to a thermionic emission model, even higher gain can be reached at lower incident power. At an incident power of about 1 pW, a conversion gain higher than half million has been estimated from the measured data.

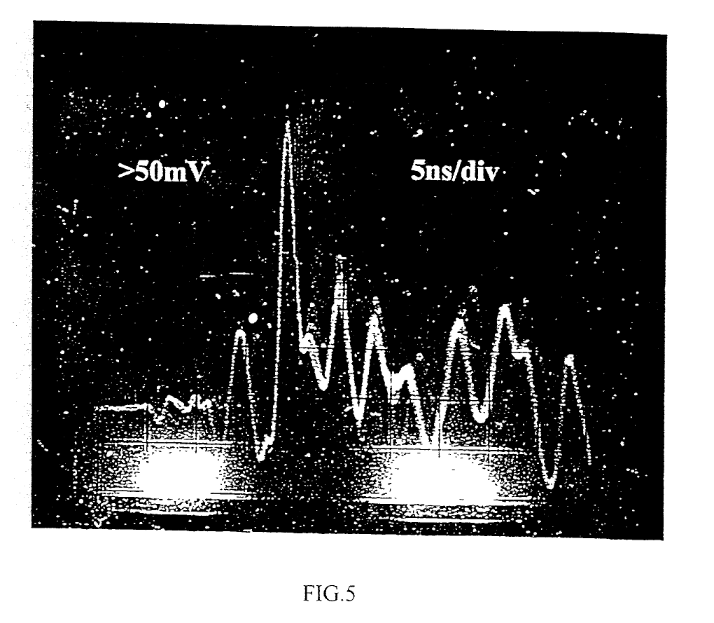

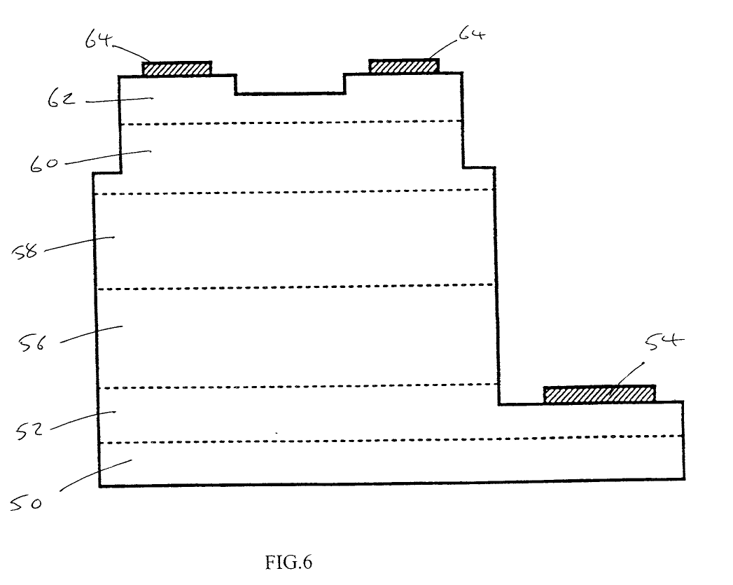

FIG. 4 shows the measured device noise as a function of the forward bias current. It can be seen clearly that only the shot noise associated with collector current appears in the device. The measured data points are shown as squares, and the line is the result of fitting the data with a straight line having a slope of 3.4×10⁻¹⁹. We can conclude that the device can provide a much higher signal-to-noise ratio at low incident power. For example, in a detection system with a p-i-n diode, a load resistor of 100 kiloOhms, an incident power of 0.1 nW, and a bandwidth of 10 k Hz, the signal-to-noise ratio at room temperature is slightly less than 2 (or 3 dB). In a similar system with the same load resistor and the same bandwidth, but with the embodiment as shown in FIG. 3 working at 2V bias, the signal-to-noise ratio (SNR) is as high as 1.9×10⁸ (or 82.8 dB). The improvement of SNR is about 80 dB.

The time response of the device to a 70 ps laser pulse is shown in FIG. 5, in which each horizontal division indicates 5 ns. About 10 such divisions are shown across the figure. The width of the central peak indicates that the FWHM (“full width of half maximum”) of the response is 2.0 ns, which corresponds to a 3 dB bandwidth of 220 MHz. Other peaks in the figure are due to reflections resulting from poor impedance matching.

In these experiments, the device is packed in a standard TO5 package, which is commonly used in low speed circuits due to its relatively large parasitic capacitance. The capacitance of the bonding pads is large compared with that required by high-speed applications. If both parasitic effects are reduced significantly, the response time of the embodiment is yet faster.

Many variations of the embodiments presented above are possible within the scope of the present invention. For example, although p-n-p structures are shown, n-p-n structures also work well. We have a mild preference for p-n-p structures since it is much easier to implant B impurities in Si to create a deeper junction, which gives the transistor a higher quantum efficiency.

Possible applications of embodiments of the invention include: (1) operating as an image sensor in a CMOS camera; (2) operating as a photodetector in a spectrometer, or being formed as a photodetector array for a spectrometer; (3) operating as an integrated receiver in a WDM local area networks; (4) performing fast image pick-up in scientific and military applications; and (5) operation in a highly sensitive light scattering measurement instrument such as an environmental monitoring or a fire alarm system.

1. A phototransistor having a substrate and a layer formed on the substrate containing laterally spaced emitter and collector regions of a first conductivity type and a base region of a second opposite conductivity type located between the emitter and collector regions, a depletion region being formed between the base region and the emitter region and including the whole of the base region.

2. A phototransistor according to claim 1 in which said depletion region includes the whole of the base region only upon a bias voltage being applied between the base and emitter regions.

3. A phototransistor having a substrate and a layer formed on the substrate containing laterally spaced emitter and collector regions of a first conductivity type and a base region of a second opposite conductivity type located between the emitter and collector regions, the base region having a width no more than about 4 μm and having a charge carrier concentration of no more than about 10¹⁶ cm⁻³.

4. A phototransistor according to claim 1, claim 2 or claim 3 in which the emitter, collector and base regions are doped regions of an element semiconductor.

5. A phototransistor according to claim 3 in which the element semiconductor is silicon.

6. A phototransistor according to any preceding claim having an insulating layer between the substrate and the emitter, collector and base regions.

7. A phototransistor according to any preceding claim in which an oxide layer is formed covering at least part of the base region.

8. A phototransistor according to any preceding claim in which the first conductivity type is n-type and the second conductivity type is p-type.

9. A phototransistor according to any preceding claim in combination with circuitry arranged to generate a bias voltage between the base and emitter regions adequate to generate a depletion region which includes the whole of the base region.

10. A method of operating a phototransistor according to any preceding claim, the method comprising using applying a bias voltage between the emitter and collector regions to generate the depletion region including the whole of the base region, exposing the phototransistor to illumination, and measuring the current conducted from the emitter region to the collector region.

11. A method according to claim 10 in which the bias voltage is in the range 2 to 6 volts.
